(19) United States
(12) Patent Application Publication
(10) Pub. No.: US 2021/0326113 A1
(43) Pub. Date: Oct. 21, 2021

(54) POWER EFFICIENT SUM-OF-PRODUCTS CALCULATION DEVICE

(71) Applicant: Igistec Co., Ltd., Hsinchu City (TW)

(72) Inventor: Tzu-Li Hung, Hsinchu County (TW)

(21) Appl. No.: 17/195,618

(22) Filed: Mar. 8, 2021

Related U.S. Application Data
(60) Provisional application No. 63/011,315, filed on Apr. 17, 2020.

(30) Foreign Application Priority Data
Jan. 7, 2021 (CN) 202110017421.5

(51) Int. Cl. G06F 7/544; H03F 3/45

(52) U.S. Cl. CPC G06F 7/5443; H03M 1/12; H03F 3/45475

(57) ABSTRACT

A sum-of-products calculation device includes a first resistance unit, a second resistance unit, a first current source, a second current source and a differential amplifier. The first resistance unit includes two resistors coupled in parallel. The second resistance unit includes two resistors coupled in parallel. The first current source is coupled to the first resistance unit for generating a first voltage. The second current source is coupled to the second resistance unit for generating a second voltage. The differential amplifier is used to receive the first voltage and the second voltage, and generate a differential signal accordingly. The differential signal is corresponding to a sum-of-products.

### CROSS REFERENCE TO RELATED APPLICATIONS

This application claims priority to Provisional Application No. 63/011,315, filed Apr. 17, 2020, and China Patent Application No. 202110017421.5, filed Jan. 7, 2021, and incorporated herein by reference in its entirety.

### BACKGROUND OF THE INVENTION

### 1. Field of the Invention

The present invention relates to a sum-of-products calculation device, and more particularly, a sum-of-products calculation device with resistance units each having two resistors coupled in parallel.

### 2. Description of the Prior Art

In the prior art, to find a sum-of-products, a plurality of pairs of coefficients should be multiplied first to obtain a plurality of products, and then the plurality of products are added together. Therefore, in order to obtain the sum-of-products, a large number of multipliers and adders must be used.

However, the circuit of the multipliers often occupies a large amount of area, and requires a lot of power. Taking artificial intelligence as an example, a weighted sum model is often used to adjust the importance of each of multiple coefficients to help artificial intelligence machines make decisions. Therefore, in artificial intelligence related circuits, a large number of sums-of-products have to be calculated, using excessive amount of area and power. At present, there is no suitable solution to calculate sums-of-products and improve the circuit performance.

### SUMMARY OF THE INVENTION

In an embodiment, a sum-of-products calculation device comprises a first resistance unit, a second resistance unit, a first current source, a second current source and a differential amplifier. The first resistance unit comprises two resistors coupled in parallel. The second resistance unit comprises two resistors coupled in parallel. The first current source is coupled to the first resistance unit for generating a first voltage. The second current source is coupled to the second resistance unit for generating a second voltage. The differential amplifier is configured to receive the first voltage and the second voltage, and generate a differential signal accordingly. The differential signal is corresponding to a sum-of-products.

In another embodiment, a sum-of-products calculation device comprises a set of operation units and an amplifier. Each operation unit comprises a first resistance unit, a second resistance unit, a first current source, a second current source and a differential amplifier. The first resistance unit comprises two resistors coupled in parallel. The second resistance unit comprises two resistors coupled in parallel. The first current source is coupled to the first resistance unit for generating a first voltage. The second current source is coupled to the second resistance unit for generating a second voltage. The differential amplifier is configured to receive the first voltage and the second voltage, and generate a differential signal accordingly. The differential signal is corresponding to a sum-of-products. The amplifier is coupled to the set of operation units, and configured to receive a set of differential signals, and generate a result signal accordingly. The result signal is corresponding to a sum of a set of sums-of-products.

In another embodiment, a sum-of-products calculation device comprises a set of operation units and an amplifier. Each operation unit comprises a first resistance unit, a second resistance unit, a first current source, a second current source and a sampling unit. The first resistance unit comprises two resistors coupled in parallel. The second resistance unit comprises two resistors coupled in parallel. The first current source is coupled to the first resistance unit for generating a first voltage. The second current source is coupled to the second resistance unit for generating a second voltage. The sampling unit is coupled to the first resistance unit and the second resistance unit, and configured to sample the first voltage and the second voltage. The first voltage and the second voltage are corresponding to a sum-of-products. The amplifier is coupled to the set of operation units, and configured to receive a set of first voltages and a set of second voltages, and generate a result signal accordingly. The result signal is corresponding to a sum of a set of sums-of-products.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a circuit diagram of a resistance unit according to an embodiment.

FIG. 2 is a circuit diagram of a sum-of-products calculation device according to an embodiment.

FIG. 3 is a circuit diagram of a sum-of-products calculation device according to another embodiment.

FIG. 4 is a circuit diagram of a sum-of-products calculation device according to another embodiment.

FIG. 5 is a circuit diagram of a sum-of-products calculation device according to another embodiment.

FIG. 6 is a circuit diagram of a y-th sampling unit in FIG. 5.

FIG. 7 is a timing diagram of controlling the sampling units in FIGS. 5 and 6.

### DETAILED DESCRIPTION

In order to obtain the sum-of-products and reduce the size and power of the circuit, the embodiment provides sum-of-products calculation devices as described below. In this description, both the “*” and “⋅” symbols are multiplication symbols. The sum-of-products described in the description can refer to the sum of a single product or the sum of a plurality of products.

FIG. 1 is a circuit diagram of a resistance unit RU according to an embodiment. The resistance unit RU comprises two resistors coupled in parallel. The resistance of one resistor is R*X, and the resistance of the other resistor is R*(1−X), where R is a predetermined resistance, X is a parameter, and 0<X<1. Therefore, if viewed from the node S, the equivalent resistance R_{OUT} can be as shown in equation (1):

$${R}_{O U T} = \frac{1}{\frac{1}{R \cdot X} + \frac{1}{R \cdot ( 1 - X )}} = \frac{{R}^{2} \cdot X \cdot ( 1 - X )}{R \cdot X + R \cdot ( 1 - X )} = R \cdot X - R \cdot {X}^{2} . \qquad ( 1 )$$

If two parameters A and B are given, where 0≤|A|≤¼ and 0≤|B|≤¼, the variable X₁ is set as shown in equation (2):

X₁=½+A+B (2)

Substitute X in equation (1) with X₁ to obtain the result R_{OUT,1} as shown in equation (3):

$$\begin{matrix}{R}_{OUT , 1} = R \cdot [ \frac{1}{2} + A + B - ( \frac{1}{4} + {A}^{2} + {B}^{2} + A + B + 2 \cdot A \cdot B ) ] \\ = R \cdot [ ( \frac{1}{4} - {A}^{2} - {B}^{2} ) - ( 2 \cdot A \cdot B ) ] .\end{matrix} \qquad ( 3 )$$

Set variable X₂ as shown in equation (4):

X₂=½−A+B (4)

Substitute X in equation (1) with X₂ to obtain the result R_{OUT,2} as shown in equation (5):

$$\begin{matrix}{R}_{OUT , 2} = R \cdot [ \frac{1}{2} - A + B - ( \frac{1}{4} + {A}^{2} + {B}^{2} - A + B - 2 \cdot A \cdot B ) ] \\ = R \cdot [ ( \frac{1}{4} - {A}^{2} - {B}^{2} ) + ( 2 \cdot A \cdot B ) ] .\end{matrix} \qquad ( 5 )$$

In other words, the aforementioned R_{OUT,1} and R_{OUT,2} can be equivalent resistances of the resistance unit RU under two different settings. By comparing equations (3) and (5), equations (6) and (7) can be obtained as follows:

Common term: ¼−A²−B² (6)

Difference term: 2·A·B (7)

That is, the abovementioned equivalent resistances R_{OUT,1} and R_{OUT,2} have the same constant term (6) and a constant term (7) with opposite polarities. If applied to an analog circuit, equations (6) and (7) can be regarded as corresponding to the common-mode signal and differential signal.

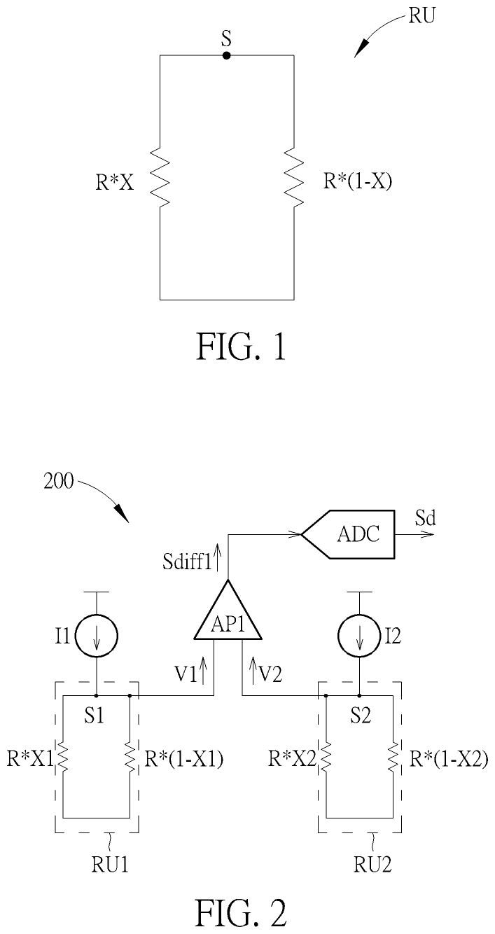

The above principle can be applied to the circuit described below to find the sum-of-products. Each of the resistance units mentioned in FIGS. 2 to 5 can be similar to the resistance unit in FIG. 1, including two resistors coupled in parallel. The resistance of one resistor is R*X, the resistance of the other resistor is R*(1−X), and the values of R and X can be adjusted as needed.

FIG. 2 is a circuit diagram of a sum-of-products calculation device 200 according to an embodiment. The sum-of-products calculation device 200 comprises a first resistance unit RU1, a second resistance unit RU2, a first current source I1, a second current source I2, and a differential amplifier AP1. The first current source I1 is coupled to the first resistance unit RU1 to generate a first voltage V1. The second current source I2 is coupled to the second resistance unit RU2 to generate a second voltage V2. The differential amplifier AP1 receives the first voltage V1 and the second voltage V2, and generates a differential signal Sdiff1 accordingly.

In FIG. 2, the equivalent resistance of the first resistance unit RU1 viewed from node S1 is R_{OUT,1} of equation (3), and the equivalent resistance of the second resistance unit RU2 viewed from node S2 is R_{OUT,2} of equation (5), voltages V1 and V2 are generated by the current source I1 and current source I2 flowing into the resistance units RU1 and RU2, respectively. Because the differential amplifier AP1 can extract the difference between the voltages V1 and V2, the differential signal Sdiff1 is corresponding to the difference term in equation (7), proportional to the product A*B of the parameters A and B. In this context, A*B can be defined as a sum-of-products, so the differential signal Sdiff1 can correspond to the sum-of-products.

As shown in FIG. 2, the device 200 may further comprise an analog-to-digital converter ADC for receiving the differential signal Sdiff1 to generate a digital signal Sd, where the digital signal Sd corresponds to the sum-of-products A*B. As mentioned above, the digital signal Sd can be analyzed to obtain the product A*B of the parameters A and B.

For example, to calculate the product of two 8-bit numbers, such as 64*17, 64 can be set as parameter A, and 17 as the other parameter B. The structure of FIG. 2 can be used to obtain the product of parameters A, B according to the digital signal Sd, and then check a lookup table to get the result of 64*17. Therefore, the use of multipliers can be avoided, thereby reducing circuit area and power consumption.

The structures of FIGS. 1 and 2 can be used to calculate a sum-of-products. Taking the application of artificial intelligence as an example, which typically requires the addition of multiple products, as shown in equation (8):

L=A₁·B₁+A₂·B₂+A₃·B₃+ . . . +Aₙ·Bₙ=Σᵢ₌₁ⁿAᵢ·Bᵢ (8)

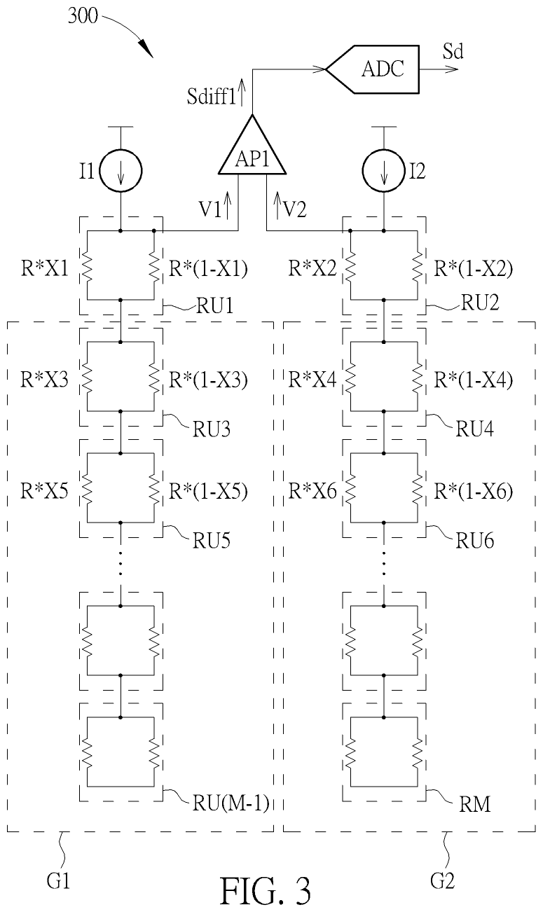

For example, Ai can be a variable, Bi can be a corresponding weight, and L is the result of a weighted calculation. To perform the calculation as shown in Equation (8), the device in FIG. 3 according to the structure and principle of FIG. 2 can be used.

FIG. 3 is a circuit diagram of a sum-of-products calculation device 300 according to another embodiment. The similarities between the device 300 and the device 200 will not be repeated. Compared with the device 200, the device 300 further comprises a first set of resistance units G1 and a second set of resistance units G2. As shown in FIG. 3, the first set of resistance units G1 is coupled to the first resistance unit RU1 in series, and the second set of resistance units G2 is coupled to the second resistance unit RU2 in series.

As shown in FIG. 3, the first set of resistance units G1 may include a third resistance unit RU3, a fifth resistance unit RU5 and other resistance units with odd serial numbers; and the second set of resistance units G2 may include a fourth resistance unit RU4, a sixth resistance unit RU6 and other resistance units with even numbers. M in FIG. 3 is an even number.

In FIG. 3, an input node of the differential amplifier AP1 is coupled to the first resistance unit RU1 and the first set of resistance units G1, which can be expressed as Σ_{α=1}(¼−A_{α}²−B_{α}²−2*A_{α}*B_{α}). The other input node of the differential amplifier AP1 is coupled to the second resistance unit RU2 and the second set of resistance units G2, which can be expressed as Σ_{α=1}(¼−A_{α}²−B_{α}²−2*A_{α}*B_{α}). Thus the sum-of-products of the differential signal Sdiff1 can be proportional to Σ_{α=1}(A_{α}*B_{α})=A₁*B₁+A₂*B₂+A₃*B₃+ . . . , where variable α is a positive integer, and 1≤α≤M/2. Thus the device 300 can obtain the sum-of-products.

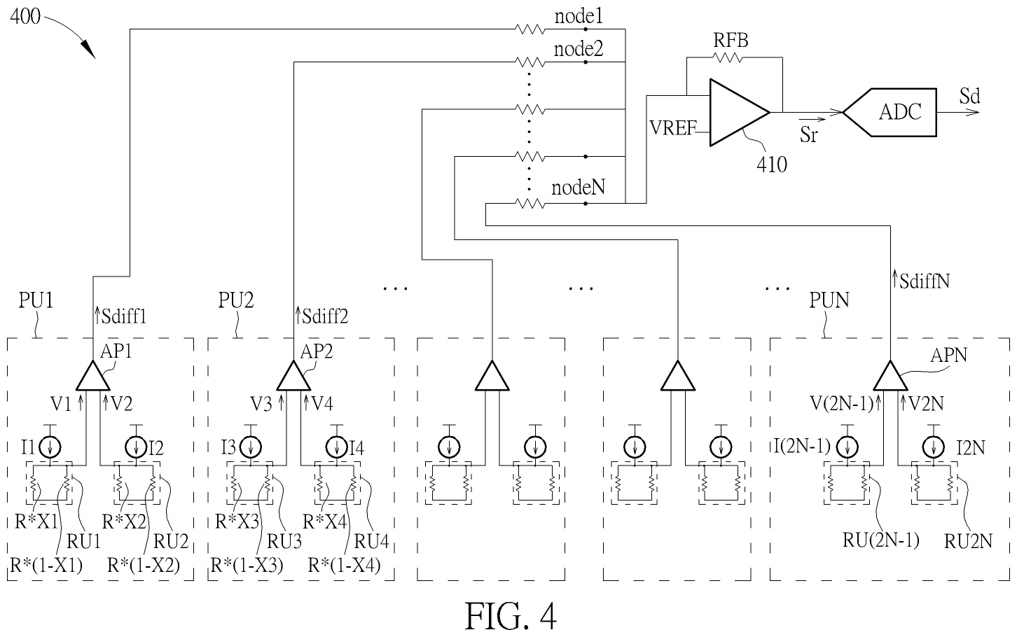

Although the circuit in FIG. 3 can be used to obtain the sum-of-products, because a plurality of resistance units are coupled in series, when current flows, the first voltage V1 and the second voltage V2 may be too high, which may exceed the acceptable range of the differential amplifier AP1, the structure of FIG. 4 can also be used to find the sum-of-products.

FIG. 4 is a circuit diagram of a sum-of-products calculation device 400 according to another embodiment. As shown in FIG. 4, the device 400 may comprise a set of operation units PU1 to PUN, and an amplifier 410. The operation units PU1 to PUN in FIG. 4 may have a similar structure. Taking the operation unit PU1 as an example, the operation unit PU1 may comprise a first resistance unit RU1, a second resistance unit RU2, a first current source I1, a second current source I2, and a differential amplifier AP1. The coupling method, the resistances of the resistors, and related operation principles are similar to those in FIG. 2, so they will not be repeated.

The operation units PU1 to PUN respectively generate differential signals Sdiff1 to SdiffN. The differential signal Sdiff1 corresponds to a sum-of-products A₁*B₁, the differential signal Sdiff2 corresponds to a sum-of-products A₂*B₂, and so on, the differential signal SdiffN corresponds to a sum-of-products A_{N}*B_{N}. The amplifier 410 receives the differential signals Sdiff1 to SdiffN to generate a result signal Sr, where the result signal Sr corresponds to the sum of the sum-of-products A₁*B₁ to the sum-of-products A_{N}*B_{N}, that is, A₁*B₁+A₂*B₂+ . . . +A_{N}*B_{N}.

In FIG. 4, the voltages from node node1 to node nodeN can be superimposed on an input node of the amplifier 410 according to the superposition principle. After the voltages at nodes node1 to nodeN each are deducted by the reference voltage VREF, the deducted voltages are divided by their respective impedances next to the nodes node1 to nodeN to generate currents, and a total current of the currents flows through a feedback resistor RFB to generate a voltage at the output node of the amplifier 410, which is the result signal Sr. Similar to FIGS. 2 and 3, the analog-to-digital converter ADC in FIG. 4 can generate a digital signal Sd based on the result signal Sr, and the digital signal Sd can correspond to the sum of the sums-of-products.

Each of the operation units PU1 to PUN can further comprise a first set of resistance units G1 and a second set of resistance units G2 as shown in FIG. 3, and thus the sets of resistance units G1, G2 are not further elaborated herein.

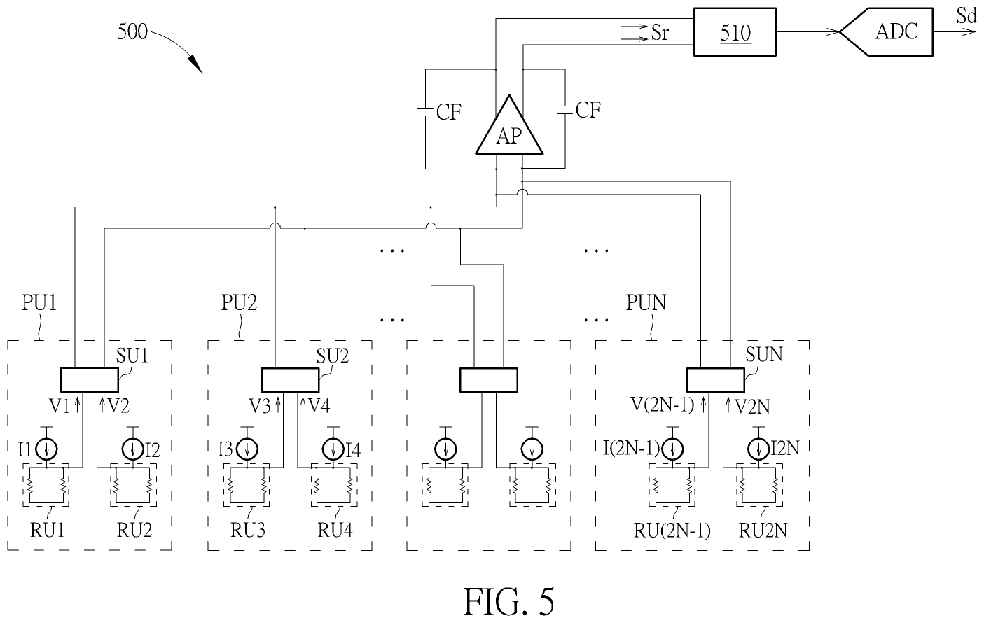

FIG. 5 is a circuit diagram of a sum-of-products calculation device 500 according to another embodiment. In the device 500, a smaller number of amplifiers are used, so the power consumption can be further reduced. The device 500 comprises operation units PU1 to PUN and an amplifier AP. The operation units PU1 to PUN in FIG. 5 are different from the operating units PU1 to PUN in FIG. 4. The operation units PU1 to PUN in FIG. 5 can have a similar structure. Taking the operation unit PU1 as an example, the operation unit PU1 comprises resistance units RU1 and RU2, current sources I1 and I2, and a sampling unit SU1. The coupling and operation of the resistance units RU1 and RU2 and the current sources I1 and I2 can be similar to the above, so the description will not be repeated. The sampling unit SU1 can sample the first voltage V1 and the second voltage V2 generated by the resistance unit RU1 and the resistance unit RU2, and output the sampling result to the amplifier AP.

In FIG. 5, the amplifier AP receives the outputs of the operation units PU1 to PUN to generate the result signal Sr. The result signal Sr corresponds to the sum of the sum-of-products A₁*B₁ to the sum-of-products A_{N}*B_{N}.

As shown in FIG. 5, the device 500 may further comprise a set of integrating capacitors CF, coupled to the amplifier AP, to accumulate a set of first voltages (for example, voltages V1, V3 to V(2N−1)) and a set of second voltages (for example, voltages V2, V4 . . . to V2N) output from the operation units PU1 to PUN. The device 500 may further comprise a differential-to-single-ended converter 510 and an analog-to-digital converter ADC. The differential-to-single-ended converter 510 converts a pair of differential signals output by the amplifier AP into a single-ended signal, and the analog-to-digital converter ADC then converts the single-ended signal to a digital signal Sd, and the digital signal Sd can be parsed to obtain the sum of products. According to an embodiment, the differential-to-single-ended converter 510 can be used optionally. If the amplifier AP has a single-ended output, the differential-to-single-ended converter 510 does not need to be used.

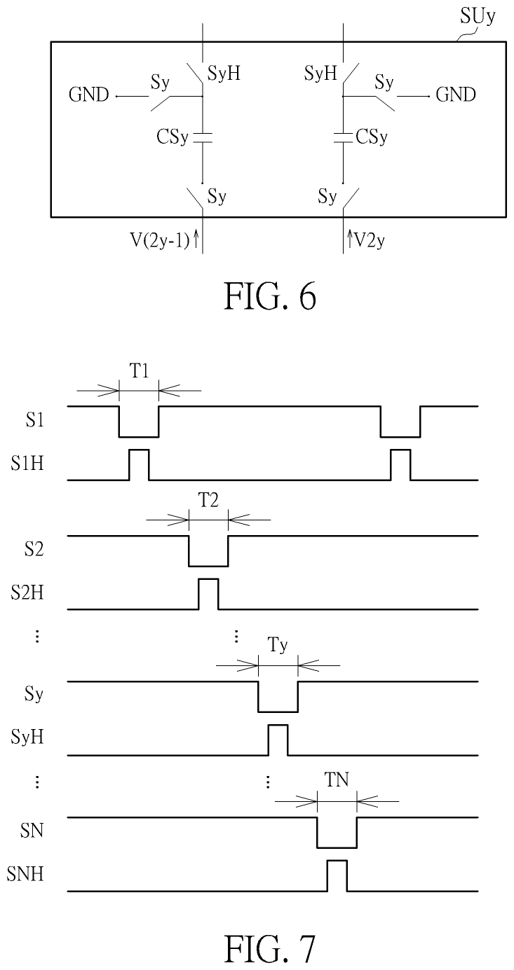

FIG. 6 is a circuit diagram of a y-th sampling unit SUy in FIG. 5, where y is an integer and 1≤y≤N. The y-th sampling unit SUy may comprise switches and capacitors CSy, and the switches are controlled by the signals Sy and SyH. For example, when the signal Sy is in the high state, the switches controlled by the signal Sy are turned on, and when the signal Sy is in the low state, the switches controlled by the signal Sy are turned off. When the signal SyH is in the high state, the switches controlled by the signal SyH are turned on, and when the signal SyH is in the low state, the switches controlled by the signal SyH are turned off. Here, the switches being high-state turned-on are only an example. Depending on the type of switches, a low-state signal may be used to turn on the switches. In FIG. 6, the switches can be coupled to the ground GND.

In other words, when the signal Sy is in the high state, the capacitor CSy of the sampling unit SUy can sample the voltages V(2y-1) and V2y; and when the signal SyH is in the high state, the sampling unit SUy can output the sampled voltages V(2y-1) and V2y.

In FIG. 5, each of the sampling units SU1 to SUN outputs the first voltage and the second voltage at the same time, and the sampling units SU1 to SUN output the first voltage and the second voltage sequentially. As shown in FIG. 7, the y-th sampling unit SUy outputs the first voltage V(2y-1) and the second voltage V2y to the amplifier AP during the time period Ty.

FIG. 7 is a timing diagram of controlling the sampling units SU1 to SUN in FIGS. 5 and 6. As shown in FIG. 7, before and after the time period T1, the sampling unit SU1 can sample the voltages V1 and V2; and in the time period T1, the sampling unit SU1 outputs the sampled voltages V1 and V2 to the amplifier AP. Similarly, in the time period T2, the sampling unit SU2 outputs the sampled voltages V3 and V4 to the amplifier AP. By analogy, in the time period TN, the sampling unit SUN can output the sampled voltages V(2N−1) and V2N to the amplifier AP.

In other words, a pair of sampled voltages can be obtained and stored in the capacitors CSy in FIG. 6 first, and then the stored charges are transferred to the integrating capacitors CF in FIG. 5 sequentially. After taking out the values of CS1 to CSN, they are converted into a digital signal Sd to obtain the sum of products.

In summary, the device provided by the embodiment can use an analog operation array to perform multiplications and additions to calculate the sum of products, thereby avoiding the use of a large number of multipliers and adders to reduce the area and power consumption of the circuit.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A sum-of-products calculation device comprising:
a first resistance unit comprising two resistors coupled in parallel;
a second resistance unit comprising two resistors coupled in parallel;
a first current source coupled to the first resistance unit for generating a first voltage;
a second current source coupled to the second resistance unit for generating a second voltage; and
a differential amplifier configured to receive the first voltage and the second voltage, and generate a differential signal accordingly wherein the differential signal is corresponding to a sum-of-products.

2. The sum-of-products calculation device of claim 1 wherein each one of the first resistance unit and the second resistance unit has a first resistor with resistance of R*X, and a second resistor with resistance of R*(1−X) wherein 0<X<1.

3. The sum-of-products calculation device of claim 1 further comprising:
a first set of resistance units coupled to the first resistance unit in series and comprising two resistors coupled in parallel; and
a second set of resistance units coupled to the second resistance unit in series and comprising two resistors coupled in parallel.

4. The sum-of-products calculation device of claim 3 wherein a first resistor of the first set of resistance units has a resistance of R*X, a second resistor of the first set of resistance units has a resistance of R*(1−X), a first resistor of the second set of resistance units has a resistance of R*X, a second resistor of the second set of resistance units has a resistance of R*(1−X) wherein 0<X<1.

5. The sum-of-products calculation device of claim 1 further comprising:
an analog to digital converter coupled to the differential amplifier and configured to generate a digital signal according to the differential signal;
wherein the digital signal is corresponding to a sum-of-products.

6. A sum-of-products calculation device comprising:
a set of operation units, each operation unit comprising:
a first resistance unit comprising two resistors coupled in parallel;
a second resistance unit comprising two resistors coupled in parallel;
a first current source coupled to the first resistance unit for generating a first voltage;
a second current source coupled to the second resistance unit for generating a second voltage; and
a differential amplifier configured to receive the first voltage and the second voltage, and generate a differential signal accordingly, the differential signal being corresponding to a sum-of-products; and
an amplifier coupled to the set of operation units, and configured to receive a set of differential signals, and generate a result signal accordingly, the result signal being corresponding to a sum of a set of sums-of-products.

7. The sum-of-products calculation device of claim 6 wherein each one of the first resistance unit and the second resistance unit has a first resistor with resistance of R*X, and a second resistor with resistance of R*(1−X) wherein 0<X<1.

8. The sum-of-products calculation device of claim 6 wherein the each operation unit further comprises:
a first set of resistance units coupled to the first resistance unit in series and comprising two resistors coupled in parallel; and
a second set of resistance units coupled to the second resistance unit in series and comprising two resistors coupled in parallel.

9. The sum-of-products calculation device of claim 8 wherein a first resistor of the two resistors of the first set of resistance units has a resistance of R*X, a second resistor of the two resistors of the first set of resistance units has a resistance of R*(1−X), a first resistor of the two resistors of the second set of resistance units has a resistance of R*X, a second resistor of the two resistors of the second set of resistance units has a resistance of R*(1−X) wherein 0<X<1.

10. The sum-of-products calculation device of claim 6 further comprising:
an analog to digital converter coupled to the amplifier and configured to generate a digital signal according to the result signal;
wherein the digital signal is corresponding to a sum-of-products.

11. A sum-of-products calculation device comprising:
a set of operation units, each operation unit comprising:
a first resistance unit comprising two resistors coupled in parallel;
a second resistance unit comprising two resistors coupled in parallel;
a first current source coupled to the first resistance unit for generating a first voltage;
a second current source coupled to the second resistance unit for generating a second voltage; and
a sampling unit coupled to the first resistance unit and the second resistance unit, and configured to sample the first voltage and the second voltage wherein the first voltage and the second voltage are corresponding to a sum-of-products; and
an amplifier coupled to the set of operation units, and configured to receive a set of first voltages and a set of second voltages, and generate a pair of differential signals accordingly, the result signal being corresponding to a sum of a set of sums-of-products.

12. The sum-of-products calculation device of claim 11 wherein the set of operation units outputs the set of first voltages and the set of second voltages sequentially.

13. The sum-of-products calculation device of claim 11 further comprising a set of integrating capacitors coupled to the amplifier for accumulating charges corresponding to the set of first voltages and the set of second voltages.

14. The sum-of-products calculation device of claim 11 further comprising a differential-to-single-ended converter coupled to the amplifier and configured to converts the pair of differential signals output by the amplifier into a single-ended signal.

15. The sum-of-products calculation device of claim 14 further comprising an analog-to-digital converter coupled to the differential-to-single-ended converter and configured to convert the single-ended signal to a digital signal; wherein the digital signal is corresponding to the sum of a set of sums-of-products.
